(19) United States
(12) Patent Application Publication
(10) Pub. No.: US 2006/0194409 A1
(43) Pub. Date: Aug. 31, 2006

(54) Process for manufacturing a SOI wafer with improved gettering capability

(75) Inventors: Roberto Capedelli, Novate Milanese (IT); Luigi Di Turi, Milano (IT); Dino Faralli, Milano (IT)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics S.R.L., Agrate Brianza (IT)

(21) Appl. No.: 11/347,801

(22) Filed: Feb. 3, 2006

(30) Foreign Application Priority Data
Feb. 3, 2005 (IT) TO 2005 A 000056

(51) Int. Cl. H01L 21/76; H01L 21/30; H01L 29/00

(52) U.S. Cl. 438/424; 438/459; 257/510

(57) ABSTRACT

Manufacturing of a wafer made of semiconductor material on insulator including the steps of: providing a composite wafer having a substrate, an insulating layer and an active layer of semiconductor material, arranged on top of one another; forming at least one deep trench within the active layer of the composite wafer, having at least one side wall; and filling at least partially the deep trench with insulating material. Prior to the filling step, the step is carried out of coating the side wall of the deep trench with a gettering layer, having the function of segregating the impurities within the active layer.

### BACKGROUND OF THE INVENTION

1. Field of the Invention

The present invention relates to a process for manufacturing an SOI wafer with improved gettering capability for segregation of the impurities within the wafer, in particular metal impurities.

2. Discussion of the Related Art

As is known, in the manufacturing of many integrated devices composite wafers are currently used, which are referred to as SOI (Silicon-On-Insulator) wafers. SOI wafers are constituted by two silicon layers and by a buried oxide layer, arranged between the two silicon layers so as to form a dielectric separation layer. The top silicon layer, generally referred to as active silicon layer, is thinner and is designed for formation of integrated electronic devices, whilst the bottom silicon layer, generally referred to as handling layer, has a greater thickness and is used for handling the SOI wafer during the manufacturing process.

Many techniques have been proposed for manufacturing of SOI wafers. For example, a very widely used technique is based upon bonding of two wafers made of monocrystalline silicon, after an oxide layer has been grown on one of the two wafers. This process is known as thermal bonding. Another technique, known as SIMOX technique, envisages the use of just one silicon wafer; within the wafer an oxide layer is formed via implantation, underneath the surface, of ions of molecular or atomic oxygen.

SOI wafers have numerous advantages as compared to wafers made of monocrystalline silicon, which include, for example, higher operating speeds of electronic devices integrated therein, and better electrical insulation between the integrated devices. Furthermore, SOI wafers are affected to a much lesser extent by problems of parasitic currents as compared, for example, to BCD (Bipolar-CMOS-DMOS) devices.

However, SOI wafers have the drawback of being subject to contamination by metal impurities, such as, for example, iron, nickel, zinc, or chrome, during the manufacturing process, for example during thermal treatments. In particular, SOI wafers are much more subject to contamination as compared to silicon wafers formed with the Czochralski method (CZ method).

Indeed, during the manufacturing process, the metal impurities remain in the active silicon layer of the SOI wafer, since the buried oxide layer acts as barrier to their vertical diffusion. In particular, the metal impurities remain trapped in the proximity of the surface of the active silicon layer, causing a degradation in the quality of the gate oxides (GOI—Gate-Oxide Integrity), and a reduction of performance and possible malfunctioning of integrated electronic devices.

A wide range of techniques are known for segregating the impurities in the active layer of the wafer, generally known as “gettering techniques”. In general, the term “gettering” refers to any mechanism that enables removal of the metal impurities from active regions of the wafer, i.e., the regions where the electronic devices are integrated, and their segregation in other inactive regions of the wafer.

Gettering techniques can be divided into extrinsic, or external, gettering techniques and intrinsic, or internal, gettering techniques. Irrespective of the technique used, the gettering process is divided in three steps: release of the impurities from their original stable state; diffusion of the impurities away from the active regions of the wafer towards a sink area; and consequent capture of the impurities.

In detail, extrinsic gettering is normally carried out at the end of the manufacturing process of the integrated devices, prior to cutting of the wafer, and envisages creation with external means of damages or areas with defects on the back surface of the wafer, opposite to the active region where the electronic devices are integrated. Said damages may, for example, be obtained via an appropriate ion implantation, via laser deformation, or via mechanical abrasion. The damaged areas act as gettering sites and, in particular, as sink areas to attract the metal impurities from the active region, and then segregate them.

Intrinsic gettering envisages, instead, exploitation of the defects existing within the wafer in order to trap the metal impurities. In particular, intrinsic gettering envisages thermal treatment of an inactive region of the wafer so as to form oxygen precipitates (SiOₓ). The stresses resulting from the formation of the oxygen precipitates create defects and dislocations that act as sink areas for the metal impurities.

Finally, other gettering techniques exist, which envisage doping the wafer by means of ion implantation or pre-deposition, for example using phosphorus ions, so as to obtain high-concentration regions. The implanted ions diffuse in the wafer and capture the metal impurities, forming ionic bonds therewith.

All these gettering techniques cannot, however, be applied, or in any case have a limited effectiveness, in the case of SOI wafers. In fact, the buried oxide layer, which generally has a thickness of around 2 μm, acts as barrier for the diffusion of the metal impurities, so that the extrinsic gettering techniques are unusable. Furthermore, since the active layer has a reduced thickness, it is not possible to provide sink regions of sufficient dimensions. Therefore, the gettering areas must be distributed within the active layer, a fact that may alter the electrical characteristics and correct operation of the electronic devices integrated therein.

### SUMMARY OF THE INVENTION

One aim of the present invention is consequently to provide a process for manufacturing a SOI wafer that will enable a solution of the aforementioned problems, and in particular that will enable an improved gettering capability for segregation of the metal impurities within the SOI wafer to be obtained.

In one embodiment, a process is provided for manufacturing a wafer made of semiconductor material on insulator, comprising: providing a composite wafer including a substrate, an insulating layer and an active layer of semiconductor material, arranged on top of one another, forming at least one deep trench within said active layer of said composite wafer, said deep trench having at least one side wall, and filling at least partially said deep trench with insulating material, wherein prior to said filling coating said side wall of said deep trench with a gettering layer.

In another embodiment, an SOI wafer is provided, comprising: a wafer made of semiconductor material on insulator, comprising a substrate, an insulating layer and an active layer of semiconductor material, arranged on top of one another; and an electrical-insulation region extending through said active layer; said electrical-insulation region including insulating material and electrically separating two regions of said active layer, wherein said electrical-insulation region further comprises gettering regions arranged between said active regions and said insulating material, and in contact with a respective one of said active regions.

### BRIEF DESCRIPTION OF THE DRAWINGS

For a better understanding of the present invention, a preferred embodiment thereof is now described, purely by way of non-limiting example and with reference to the attached drawings, wherein:

FIGS. 1-8 are cross-sectional views of an SOI wafer in successive steps of a manufacturing process according to a first embodiment of the present invention; and

FIG. 9 is a cross-sectional view of an SOI wafer at the end of a manufacturing process according to another embodiment of the present invention.

### DETAILED DESCRIPTION

One idea underlying the present invention is that of forming a layer of a material having gettering properties (referred to in what follows as gettering layer), in particular polycrystalline silicon, on side walls of insulation trenches provided within the active layer of the SOI wafer. In this way, an extensive region with gettering capability is obtained directly within the active layer, thus overcoming the problems due to the presence of the buried oxide layer.

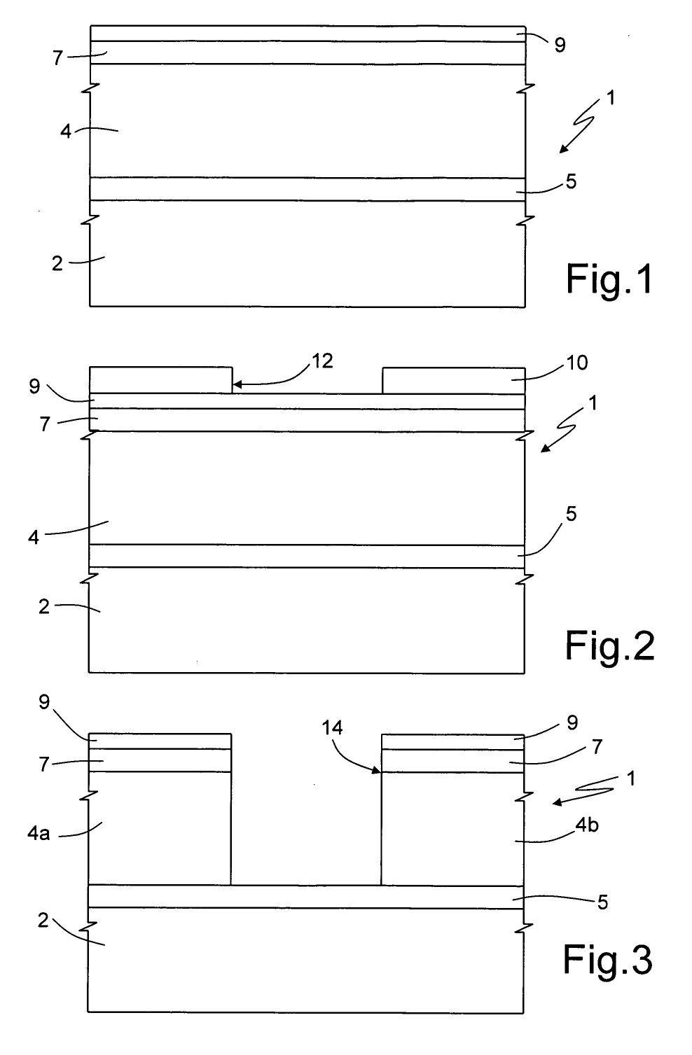

In detail, and with reference to FIGS. 1-8, a wafer 1 of semiconductor material on insulator (in the example a SOI wafer) includes a substrate 2, made for example, of n-type silicon, an active layer 4, also made, for example, of n-type silicon, and an insulating layer 5, for example, an oxide layer. The substrate 2 has mainly a function of mechanical support during the manufacturing process of the wafer 1, whilst the active layer 4, having a thickness of, for example, 9 μm, is designed for integration of electronic devices. The insulating layer 5 has a thickness of, for example, 2 μm, and has the function of electrically insulating the active layer 4 with respect to the substrate 2. In particular, the active layer 4 and the substrate 2 are fixed via a thermal bonding technique.

A field-oxide layer 7 is formed on the active layer 4. The field-oxide layer 7, made, for example, of silicon dioxide, can be deposited or grown on the active layer 4 via a thermal oxidation in an oxygen-rich environment, and have a thickness of 1.35 μm.

On the field-oxide layer 7 a silicon-nitride (Si₃N₄) layer 9 is then deposited, for example via a low-pressure chemical vapor deposition (LPCVD), or else via a plasma-enhanced chemical vapor deposition (PECVD), or via any other suitable technique. The silicon-nitride layer 9 has a thickness of, for example, 0.2 μm.

Then (FIG. 2), the silicon-nitride layer 9 is covered by a resist layer 10, which is defined so as to form an opening 12.

Next (FIG. 3), underneath the opening 12 a deep trench 14 is formed via any anisotropic dry chemical etching technique, for example via reactive-ion etching (RIE). The trench 14 traverses the silicon-nitride layer 9, the field-oxide layer 7 and the entire active layer 4, and reaches the insulating layer 5. The deep trench 14 acts as an insulation trench between two active regions, designated by 4a and 4b, which are electrically insulated from one another.

The resist layer 10 is then removed from the surface of the wafer 1.

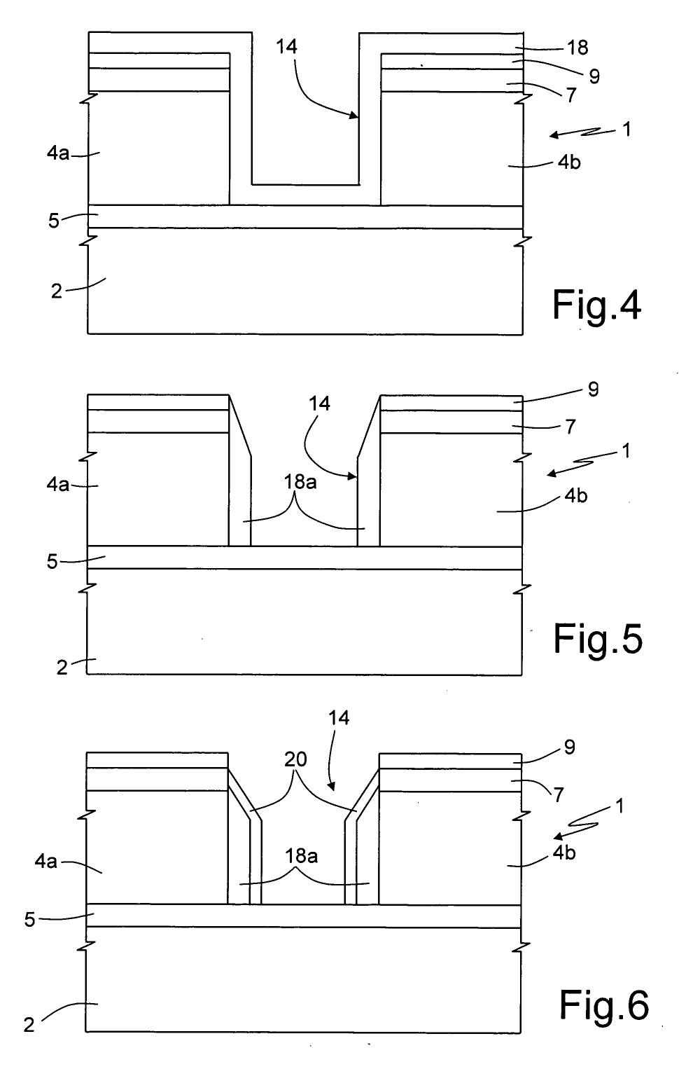

Then (FIG. 4), a gettering layer 18 is deposited on the surface of the wafer 1, for example a polysilicon layer having a thickness of 0.45 μm. In particular, the gettering layer 18 coats the side walls and the bottom of the deep trench 14.

Next (FIG. 5), an “etch-back” of the gettering layer 18 is performed, so that the portions of the gettering layer 18 overlying the active silicon regions 4a, 4b and the bottom of the deep trench 14 are removed. In addition, the remaining portions of the gettering layer 18, which coat the walls of the deep trench 14 and are designated by 18a, are etched.

Then (FIG. 6), the gettering portions 18a are oxidized, and oxide layers 20 are thus formed on the gettering portions 18a. In this step, the field-oxide and field-nitride layers 9, 7 are used as a mask to prevent oxidation of the surface of the active layer 4. The oxide layer 20 resulting from the oxidation has a thickness of, for example, 0.35 μm.

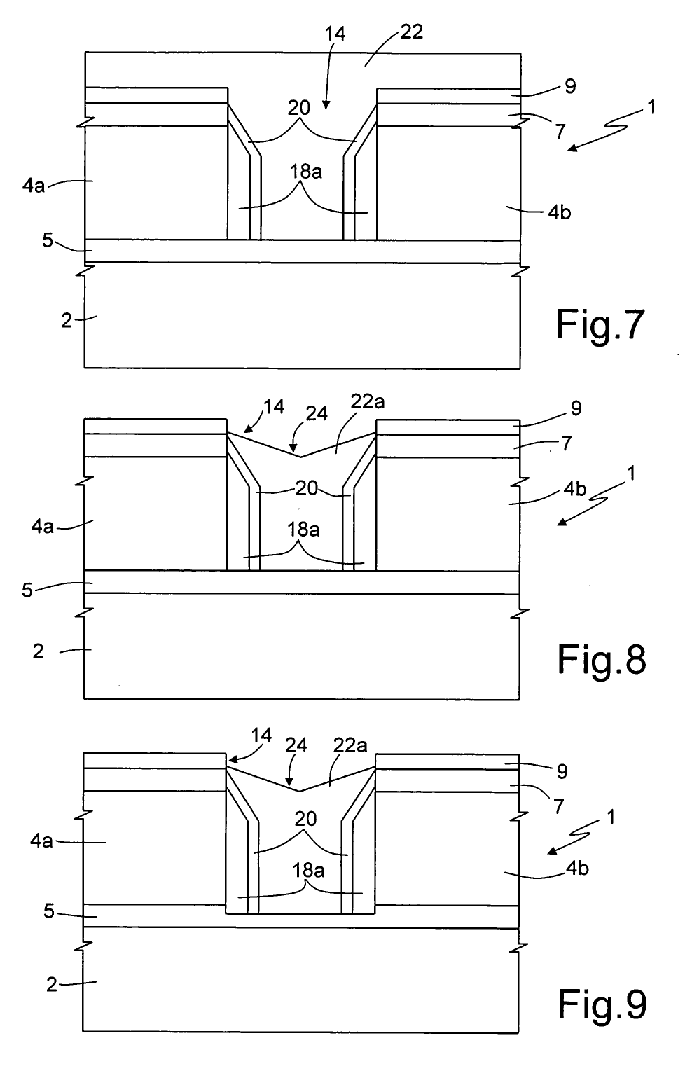

Next (FIG. 7), a layer of TEOS (tetraethyl orthosilicate) 22 is deposited, for example via a chemical vapor deposition, on the surface of the wafer 1, until the deep trench 14 is completely filled. The thickness of the TEOS layer 22 on top of the active regions 4a, 4b is, for example, 1.2 μm.

Then (FIG. 8), the TEOS layer 22 undergoes an etch-back process, at the end of which the TEOS is removed completely on top of the active regions 4a, 4b and remains only within the deep trench 14, forming a filling region 22a. In particular, the etch-back can occur either chemically by reactive-ion etching or via a mechanical planarization operation (CMP—Chemical Mechanical Polishing).

Next, the filling region 22a undergoes a densification process via thermal annealing.

Finally, in a way not shown, the electronic and/or electromechanical devices are formed within the active regions 4a, 4b.

Accordingly, prior to the manufacturing of the electronic devices, the wafer 1 has an electrical-insulation region 24 formed by the gettering portions 18a, by the oxide layers 20, and by the filling region 22a. Within this electrical-insulation region 24, the gettering portions 18a are in direct contact with the active regions 4a, 4b and have the function of segregating the contaminating impurities, which are located in the active regions 4a, 4b as a result of the manufacturing process; the filling region 22a, which extends between the surface of the active layer 4 and the insulating layer 5, guarantees the electrical insulation between the active regions 4a, 4b.

The described process for manufacturing an SOI wafer has a number of advantages.

In particular, the polysilicon layer deposited on the side walls of the insulation trench represents an extensive gettering region internal to the active layer. In fact (see, for example, Frigeri et al. “Evaluating the effects of internal gettering in epi Si”, Solid State Technology, November 2003), the capability of the polysilicon grain boundaries for capturing the impurities within silicon layers is well known and documented.

Thanks to the improved gettering capability, the quality and integrity of the gate oxides formed on top of the active region is improved.

Furthermore, when the manufacturing process already envisages the formation of trench insulations, the gettering region is obtained by exploiting already existing structures. Consequently, an improved gettering effect is achieved as compared to traditional techniques, without occupying additional area of the SOI wafer.

The gettering effect due to the presence of the polysilicon layer also increases the average life of the minority carriers. In fact, the metal impurities and the crystallographic defects act in the silicon as recombination centers for electrons and holes; the greater the presence of these recombination centers, the faster the reduction in the average life of the minority carriers.

Furthermore, the described process is particularly advantageous in the case of SOI wafers obtained with thermal bonding techniques of, in so far as SOI wafers obtained using said techniques have an even smaller gettering capability than that of SOI wafers obtained using different techniques.

Finally, it is clear that modifications and variations can be made to the process for manufacturing a SOI wafer described herein without thereby departing from the scope of the present invention, as defined in the appended claims.

In particular, the SOI wafer can be obtained using a technique other than the thermal bonding technique. For example, the active layer may comprise also an epitaxially grown portion.

Furthermore, a plurality of insulation trenches with side walls coated with a gettering layer may be envisaged. In this case, each trench delimits, with adjacent trenches, active regions electrically insulated from one another, which integrate the desired electronic devices.

Finally, the thickness of the insulation trench can be greater than the one described; for example, the insulation trench can extend partly within the insulating layer, as shown in FIG. 9. Given that the gettering portions 18a terminate in any case within the insulating layer 5, also in this case the electrical insulation between the active regions 4a, 4b and the substrate 2 is guaranteed.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A process for manufacturing a wafer made of semiconductor material on insulator, comprising:
providing a composite wafer including a substrate, an insulating layer and an active layer of semiconductor material, arranged on top of one another;
forming at least one deep trench within said active layer of said composite wafer, said deep trench having at least one side wall; and
filling at least partially said deep trench with insulating material,
wherein, prior to said filling, coating said side wall of said deep trench with a gettering layer.

2. The process according to claim 1, wherein said gettering layer includes polysilicon.

3. The process according to claim 1, wherein said deep trench electrically separates two regions of said active layer, and wherein said coating comprises:
depositing said gettering layer on said wafer; and
removing said gettering layer from the top of said regions and from a bottom surface of said deep trench.

4. The process according to claim 1, wherein forming at least one deep trench includes:
etching said active layer as far as said insulating layer; and
interrupting said etching when said insulating layer is reached.

5. The process according to claim 1, wherein forming at least one deep trench includes:
etching said active layer as far as said insulating layer;
etching partially said insulating layer.

6. The process according claim 1, wherein said filling comprises:
forming an oxide layer on said gettering layer; and
filling said deep trench with a TEOS layer.

7. The process according to claim 1, wherein said semiconductor material is monocrystalline silicon, and said composite wafer is obtained by means of bonding.

8. A wafer made of semiconductor material on insulator, comprising a substrate, an insulating layer and an active layer of semiconductor material, arranged on top of one another; and an electrical-insulation region extending through said active layer; said electrical-insulation region including insulating material and electrically separating two regions of said active layer,
wherein said electrical-insulation region further comprises gettering regions arranged between said active regions and said insulating material, and in contact with a respective one of said active regions.

9. The wafer according to claim 8, wherein said gettering regions are made of polysilicon.

10. The wafer according to claim 8, wherein said electrical-insulation region and said active layer have substantially the same thickness, and said gettering regions extend from a top surface of said wafer as far as said insulating layer.

11. The wafer according to claim 8, wherein said electrical-insulation region has a thickness greater than that of said active layer and extends partially within said insulating layer, and said gettering regions extend from a top surface of said wafer and partially within said insulating layer.

12. The wafer according to claim 8, wherein said electrical-insulation region includes an oxide layer arranged between each of said gettering regions and said insulating material.

13. The wafer according to claim 12, wherein said insulating material is TEOS.

14. The wafer according to claim 8, wherein said substrate and said active layer are made of monocrystalline silicon.
